(19) United States
(12) Patent Application Publication
(10) Pub. No.: US 2006/0022213 A1
(43) Pub. Date: Feb. 2, 2006

(54) TO-can heater on flex circuit

(76) Inventor: Joshua D. Posamentier, Oakland, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/911,335

(22) Filed: Aug. 2, 2004

(51) Int. Cl. H01L 33/00

(52) U.S. Cl. 257/99

(57) ABSTRACT

An optical device, such as a vertical cavity surface emitting laser (VCSEL) may be housed in a hermetic enclosure such as a transistor-outline (TO) can and form part of a transmitter optical subassembly (TOSA). The TOSA may be connected to a printed circuit board (PCB) with a flexible circuit. A heating element provided on the flexible circuit heats the hermetic enclosure to improve radio frequency (RF) performance of the optical device in cold ambient conditions.

### FIELD OF THE INVENTION

Embodiments of the present invention relate to hermetic packages and, more particularly, to heated hermetic packages.

### BACKGROUND INFORMATION

Optoelectronic components or active optical devices such as diode lasers, light-emitting diodes (LEDs), and photodiode detectors are used for a multitude of applications. Most optoelectronic components are typically sealed inside a hermetically sealed package for performance requirements and operational stability. For high-speed optical telecommunication applications hermetic sealed packages are standard.

Transistor-Outline (TO) packages, or TO-cans as they are often referred, are one of the more inexpensive hermetic packages used to house optoelectronic components. Conventional TO-cans include a generally cylindrical metal cap and a metal header or base, to which the metal cap is attached. The outline or silhouette of the TO-can tends to resemble that of a discrete transistor; hence the name. In such packages, metal-based bonding techniques such as, for example, brazing or fusion welding, are often required to provide a hermetic seal between the metal cap and the header. To weld the metal cap onto the header, the header is typically formed of a metallic material such as Kovar™ or stainless steel.

Optical transceivers operating at line rates of 10 gigabits/second (Gb/s) have matured rapidly over the last few years and are currently available in a wide variety of form factors, each addressing a range of link parameters and protocols. These form factors are the result of Multi-Source Agreements (MSAs) that define common mechanical dimensions and electrical interfaces. The first MSA was the 300-pin MSA in 2000, followed by XENPAK, X2/XPAK, and XFP. Each of the transceivers defined by the MSAs have unique advantages that fit the needs of various systems, supporting different protocols, fiber reaches, and power dissipation levels.

Optical transceivers are expected to operate across a wide ambient temperature range. For example, some of the MSAs may call for the transceiver to operate in conditions as cold as −25 degrees Celsius to as hot as 85 degrees Celsius. However, for high-speed applications, as the device operates heat is generated and a heat sink may be necessary to dissipate heat efficiently from the package. Typical heat sinks include cooling fins attached to a heat sink base that is in contact with the header or base of the optoelectronic package. Larger and more costly “butterfly” packages may be cooled with a passive heat sink or Peltier thermo-electric device. TO-cans are inexpensive and typically uncooled. Further, TO-cans are often used to package vertical cavity surface-emitting lasers (VCSELs) which do not require cooling at higher temperatures.

During cold operation however, VCSELs tend to have very poor radio frequency (RF) performance at the lower end of the temperature range. One can adjust some of the operating parameters to improve cold temperature performance, however this negatively impacts higher temperature performance.

### BRIEF DESCRIPTION OF THE DRAWINGS

FIG. 1 is an open view of a hermetically sealable transistor outline can (TO-can) for packaging a variety of optical and electrical components;

FIG. 2 is the TO-can shown in FIG. 1 sealed with its cap;

FIG. 3 is a Transmitter Optical Subassembly (TOSA) mounted on a flexible circuit including a TO-can heating element; and

FIG. 4 is a block diagram of an optoelectronic transceiver with a heated TO-can for cold temperature operation.

### DETAILED DESCRIPTION

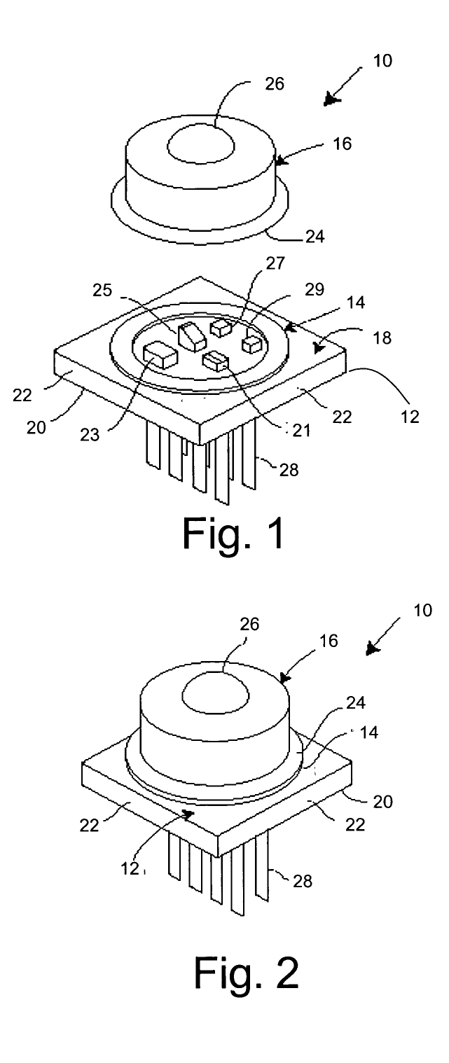

Referring now to the drawings, and more particularly to FIG. 1, there is shown a transistor-outline package (TO-can) 10 for housing an optoelectronic assembly. The package 10 includes an insulating base or substrate 12, a metal sealing member 14, and a metal cover 16. Preferably, the insulating base 12 is formed of a material with good thermal conductivity for directing dissipated heat away from the optoelectronic assembly. By using a high thermal conductivity material, the insulating base 12 is capable of effectively dissipating the heat of un-cooled active optical devices, e.g., diode lasers, and can incorporate integrated circuits, e.g., diode driver chips, into the optoelectronic package 10.

Suitable materials for the insulating base 12 include ceramics such as alumina, beryllium oxide (BeO), and aluminum nitride (AlN). The insulating base 12 includes an upper surface 18, a lower surface 20, and four substantially flat sidewalls 22 (two of which are shown) extending downwardly from the upper surface 18. The thickness of the insulating base 12 may be approximately 1 mm. Of course, it should be understood that the insulating base 12 could be thicker or thinner as desired. The insulating base 12 may be configured as a multilayer substrate having a plurality of levels. Multiple metal layers may be provided at each of the plurality of levels, and joined together (e.g., laminated) on the insulating base 12.

Various devices may be housed within the package 10. For example, an active optical device 21 and its associated integrated circuit chip 23, a passive optical device 25, and various other electrical components 27 and 29 are located within an inner region of the metal sealing member 14. The active optical device 21 may be, for example, a multimode vertical cavity surface-emitting laser (VCSEL) 21.

At least one electrical lead 28 may be included adapted to communicate signals from the optoelectronic and/or electrical components housed inside the package 10 to components located external to the package 10 on a printed circuit board, for example. The leads 28 may be circular or rectangular in cross-section, as shown. Alternatively, the insulating base 12 may be operatively coupled to the printed circuit board using solder connections such as, for example, ball grid array connections and/or a flex circuit. Flex circuit connections for TO-can devices are shown for example in U.S. Pat. No. 6,617,518 to Ames et al.

The cover 16, may be formed of Kovar™ or other suitable metal, may be hermetically sealed to the metal sealing member 14 to contain and fully enclose the optoelectronic and electrical components mounted to the upper surface 18 of the insulating base 12, and to thereby seal off the TO-can 10. The insulating base or header 12 may comprise ceramic or may comprise glass feedthroughs. Use of such a hermetically sealed cover 16 acts to keep out moisture, corrosion, and ambient air to therefore protect the generally delicate optoelectronic and electrical components housed inside the package 10.

The cover 16 includes a transparent portion 26 such as, for example, a flat glass window, ball lens, aspherical lens, or GRIN lens. The optoelectronic components, such as the VCSEL 25, are mounted to the insulating base 12 within the package 10 in a manner such that light is able to pass to or from them through the transparent portion 26. Typically, the transparent portion 26 is formed of glass, ceramic, or plastic. To avoid effects on the optoelectronic and electrical components housed within the package 10, the transparent portion 26 of the cover 16 may be provided with an antireflection coating to reduce optical loss and back-reflection.

Referring to FIG. 2, there is shown the TO-can package 10 with the cap 16 sealed in place. Like items are from FIG. 1 are labeled with like reference numerals and therefore a discussion may not be repeated. As shown in FIG. 2, cover 16 may be circular or cylindrical in shape. However, the cover 16 may have a square or rectangular shape instead. The cover 16 may include a lower peripheral edge or rim 24 having a shape that is generally complementary to the shape of the sealing member 14 so that the rim 24 of the cover 16 can be hermetically sealed to the sealing member 14. The interior of the sealed package 10 may be filled with an inert gas, or vacuum environment that protects them and prevents degradation in their performance and/or lifetime.

Optical transceivers may comprise a transmitter portion and a receiver portion, each of which may be housed in individual TO-cans 10 as described above. The transmitter portion may use a multimode VCSEL 25 to create the light pulses on to which data may be modulated. This transmitter portion may be referred to the Transmitter Optical Subassembly (TOSA). Similarly, a photodiode or photo detector chip may be used in the receiver portion to convert received light pulses for further processing. The receiver portion may be referred to as the Receiver Optical Subassembly (ROSA).

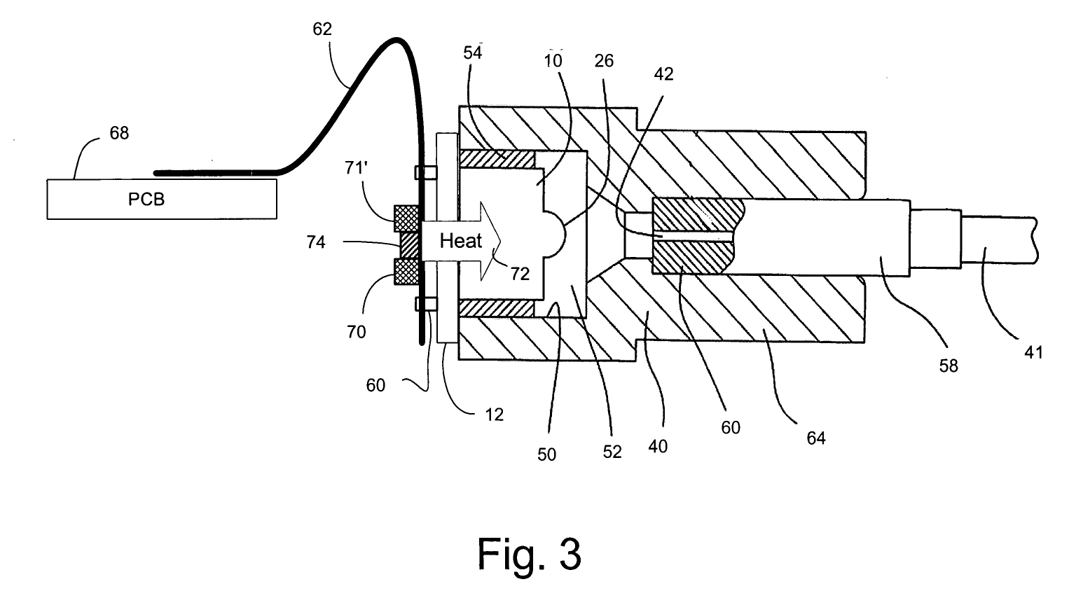

Referring now to FIG. 3, the TO-can package 10 discussed above that hermetically houses the components of the ROSA or TOSA, may be placed in an additional, outer housing 40 that is adapted to align an optical fiber 42 to the transparent window 26 of the TO-can 10. While the TO-can 10 is shown with a convex window 26, the TO-can may comprise a metal can with a flat angled window 26. The housing 40 may form the female portion of a small form factor (SFF) pluggable connector, such as an LC connector, or other standardized removable connector for optical transceivers. The housing 40 comprises a sleeve 50 forming a socket 52 into which the TO-can 10 is fitted. Spacers 54 may be used between the TO-can 10 and the inner wall 56 of the socket 52. The substrate 12, also referred to as the TO-can “header” 12, butts to the housing 40. A fiber 42 having an outer protective sheathing 41 is held by the male portion of the connector 58 comprising a ferrule 60 centering a fiber 42. The ferrule 60 may be plugged into a ferrule receptacle 64 formed in the housing 40 such that the fiber 42 is optically aligned with the lens 26 in the top of the TO-can 10.

As shown, the TO-can 10 comprises flex connector pins 60 for electrically connecting to a flexible circuit 62. The flexible circuit 62 may be, in turn, electrically connected to a printed circuit board (PCB) 68. The flex circuit 62 may contain multiple traces on multiple layers for making a plurality of connections between the TO-can 10 and the PCB 68. A heating element 70 may be electrically connected to flex circuit 62 at the TO-can header 12. The heating element 70 may comprise one or more resistive elements shown as 70 and 70′, and may comprise surface mount (SMT) resistors. In cold temperature conditions current may be made to flow through the heating element(s) 70 and 70′. The heat generated may be transferred through the TO-can header 12 to warm the components therein, such as a multi-mode VCSL (shown as 25 in FIG. 2). This heat transfer is illustrated by arrow 72. The thermal conductivity of the material of the insulating base or header 12 makes it possible to efficiently extract the heat from the TO-can 10 as well as introduce heat to the TO-can 10.

A temperature sensor 74, such as a thermistor, may be provided to sense the temperature of the header 12 to estimate the temperature of the VCSEL 25. The temperature sensor 74 may also be located within the TO-can 10 (such as 27 in FIG. 2) to output a signal through one of the connector leads 60 for greater accuracy.

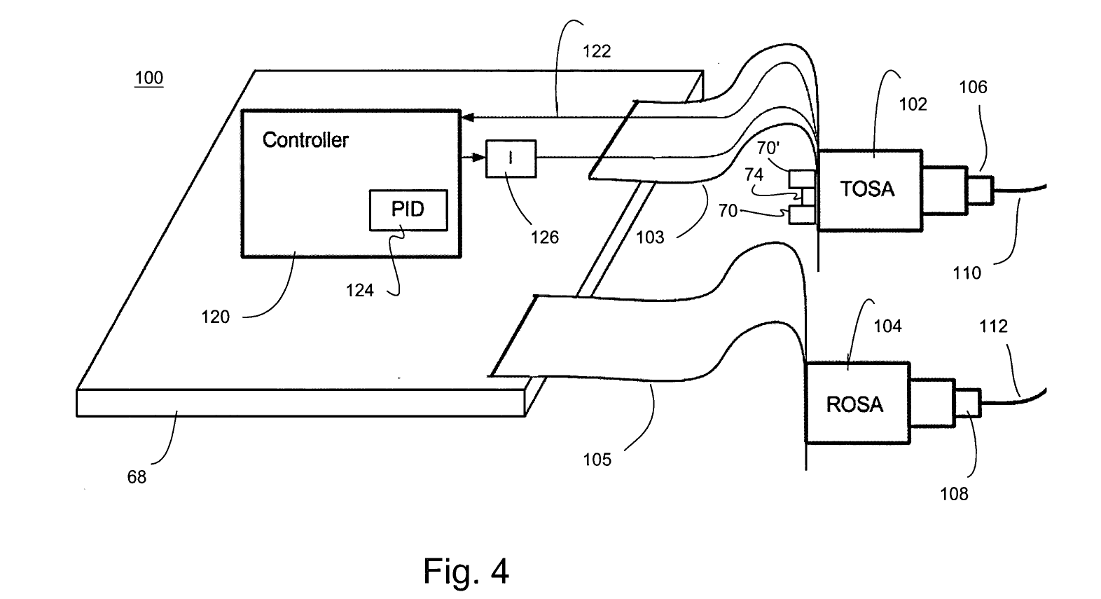

FIG. 4 illustrates an optical transceiver 100 according to embodiments of the invention. The transceiver 100 may comprise a TOSA 102 and a ROSA 104, each comprising a SFF connection, 106 and 108, respectively. The TOSA 102 is connected to the PCB 68 via a flex connector 103 and the ROSA 104 via flex connector 105. A fiber for transmitting data 110 may be plugged into the TOSA 104 and a fiber for receiving data 112 may be plugged into the ROSA 102. The TO-Can (not shown) within the TOSA 102 may be heated via the heating elements 70 and 70′.

A controller 120 on the printed circuit board 68 may comprise a closed feedback loop 122 wherein data from the temperature sensor 74 is fed back to a Proportional, Integral, Derivative (PID) controller 124 which controls the amount of current being sourced 126 through the heating elements 70 as a function of ambient/can temperature. PID controllers are well known in the art and use a transfer function to automatically adjust some variable, in this case current, to hold a measured variable, in this case temperature, at a set-point. The PID controller 126 transfer function is calibrated to keep the TOSA 102 from going below a minimum temperature, for example room temperature, while not contributing any additional heat above that set point.

Because of the thermal transfer properties between certain TOSA 102 and the TO-can headers 18 and housings or barrels 40, heating should be efficient since little heat will be lost to the housing 40 or the PCB 68. In one embodiment, the barrel 40 and its surrounding contact points may be made from injection molded Ultem. Of course many other connections not shown may be made over the flex circuits 103 and 105 between the TOSA 102 and the PCB 64 and the ROSA 104 and the PCB 64.

The heating elements 70 and 70′ may be connected to the TOSA 102 ground through a wide thermally conductive trace on the flex connector 103. Current may be supplied from the current source 126 via a smaller, non-thermally conductive trace and may run at maximum available voltage to minimize current draw for a given power dissipation and hence minimize both thermal and voltage loss in the trace.

Without heating, RF performance of a 850 nanometer (nm) Multimode VCSEL TOSA is severely compromised at low temperatures. Embodiments of the invention may provide a cost effective and efficient way to insure a level of RF performance at lower temperatures. Energy considerations to operate the heating elements 70 may be negligible. While the power requirements for the heating elements increase as the temperature drops, the overall power consumption of the transponder itself also diminishes as temperature drops. This may result in nearly constant transponder power consumption across the specified temperature range.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

What is claimed is:

1. An apparatus, comprising:
a hermetic package;
a flexible circuit to operatively connect the hermetic package to a board;
a heating element operatively connected to the flexible circuit to heat the hermetic package.

2. The apparatus as recited in claim 1, further comprising:
a controller on the board to control a current to the heating element.

3. The apparatus as recited in claim 2 wherein the controller comprises a Proportional, Integral, Derivative (PID) controller.

4. The apparatus as recited in claim 2 further comprising:
a temperature sensor operatively connected to the flexible circuit to provide feedback to the controller.

5. The apparatus as recited in claim 1 wherein the heating element comprises one or more surface mount (SMT) resistors.

6. The apparatus as recited in claim 1 wherein the hermetic package comprises transistor outline (TO) can housing a vertical cavity surface emitting laser (VCSEL).

7. The apparatus as recited in claim 6 wherein the TO can comprises a transmitter optical subassembly (TOSA).

8. A method, comprising:
packaging a vertical cavity surface emitting laser (VCSEL) in a hermetic enclosure; and
supplying heat to the hermetic enclosure to heat the VCSEL to a pre-selected temperature.

9. The method as recited in claim 8, further comprising:
connecting the hermetic package and a heating element to a controller with a flexible circuit; and
supplying current to the heating element via the controller.

10. The method as recited in claim 9 further comprising:
providing a feedback signal indicative of temperature of the VCSEL to the controller.

11. The method as recited in claim 8 further comprising:
placing the hermetic enclosure in a transmitter optical subassembly (TOSA).

12. The method as recited in claim 8 wherein the supplying heat comprises:
operatively connecting at least one heating element on the flexible circuit in proximity of the hermetic enclosure.

13. An optical system comprising:
a transmitter optical subassembly (TOSA);
a laser packaged in a hermetic enclosure within the TOSA;
a flexible circuit to operatively connect the TOSA to a printed circuit board;
at least one heating element connected to the flexible circuit; and
a controller on the printed circuit board to supply a current to the heating element to heat the hermetic enclosure.

14. The optical system as recited in claim 13 further comprising:
a temperature sensor to supply a feedback signal to the controller indicative of a temperature of the hermetic enclosure.

15. The optical system as recited in claim 13 wherein the at least one heating element comprises a surface mount (SMT) resistor.

16. The optical system as recited in claim 13 wherein the hermetic enclosure comprises a transistor outline (TO) can.

17. The optical system as recited in claim 16 wherein the controller comprises a Proportional, Integral, Derivative (PID) controller.

18. The optical system as recited in claim 16 wherein the at least one heating element transfers heat to a header of the TO can.

19. The optical system as recited in claim 13 further comprising:
a receiver optical subassembly (ROSA) connected to the printed circuit board through a second flexible connector.
